(19) United States
(12) Patent Application Publication
(10) Pub. No.: US 2009/0219705 A1
(43) Pub. Date: Sep. 3, 2009

(54) Connecting Component for Electrically Connecting a Sensor Element and an Evaluation Circuit

(76) Inventors: Oliver Glock, Stuttgart (DE); Holger Scholzen, Stuttgart (DE); Mathias Klenk, Loechgau (DE); Juergen Krueger, Remseck-Aldingen (DE)

Correspondence Address: KENYON & KENYON LLP, ONE BROADWAY, NEW YORK, NY, 10004, US

(21) Appl. No.: 11/920,806

(22) PCT Filed: Mar. 29, 2006
(86) PCT No.: PCT/EP2006/061145

§ 371 Date: Mar. 17, 2009

(30) Foreign Application Priority Data
May 17, 2005 (DE) 10 2005 022 674.4

(51) Int. Cl. H05K 7/16

(52) U.S. Cl. 361/807

(57) ABSTRACT

A device for electrically connecting a sensor element, which is accommodated in an engine add-on component, to evaluation electronics. The engine add-on component and the evaluation electronics are electrically connected to one another via contacting lines. The evaluation electronics is accommodated in a swiveling part of a hybrid holder which is movable relative to a part of the hybrid holder which is attached to the engine add-on component.

### FIELD OF THE INVENTION

The present invention relates to the electrical connecting component between a sensor element and an evaluation circuit, in particular a sensor element used in an engine add-on component for internal combustion engines.

### BACKGROUND INFORMATION

Connecting technologies, which require a mutually defined and fixed connection of the components to be electrically contacted with one another, have been previously used for establishing an electrically conducting connection between a sensor element and an evaluation circuit which evaluates the signals of the sensor element. Known contacting methods for establishing an electrical connection are, among other things, bonding, gluing, and welding. Novel contacting methods such as, for example, three-dimensional bonding (3-D bonding), are not yet suitable in practice and hold great technical risks.

The contacting methods described above for establishing an electrical connection between a sensor element and an evaluation circuit may result in great limitations with regard to the construction of a connecting component and great limitations with regard to a subsequent accessibility of the components electrically connected to one another such as, for example, a sensor element and an evaluation circuit.

If, for example, an engine add-on component, such as, for example, a glow plug and an evaluation circuit are isolated from each other in a hybrid form, it is necessary to separate an electrical connection established by way of gluing, bonding, or welding again in order to disassemble an engine add-on component in the form of a glow plug for compression-ignition internal combustion engines.

### SUMMARY OF THE INVENTION

An object of the present invention is to provide an electrical connection between a sensor element and an evaluation circuit via a connecting element which enables the use of well-proven manufacturing methods despite constructions of engine add-on components which are becoming increasingly complex.

Following the approach provided according to the present invention, a hybrid holder is used which, with one part, is lockable in a form-locked manner in the upper area of the engine add-on component, such as, for example, a glow plug, and whose other part which accommodates evaluation electronics (hybrid) may be raised around a swivel axis relative to the first part. The swiveling part of the hybrid holder, which is adjustable from a lowered position to a raised position, preferably includes a trough-shaped recess in which the hybrid is inserted. On one side of the trough-shaped recess, a plug connection component may be formed via which the hybrid holder and the accommodated evaluation electronics may be connected to an engine controller.

While the first part of the hybrid holder may be accommodated in a form-locked manner on the engine add-on component, such as, for example, a glow plug for compression-ignition internal combustion engines, the other part of the hybrid holder, which contains the trough-shaped recess for accommodating the hybrid, is able to be turned upward from a lowered position into a raised position around a swivel axis, be it a film hinge, be it a rotary axis, or be it a tilting joint. The raised position of the further part represents the installation position on the engine add-on component. In this case, the hybrid holder may be connected to a signal line leading to the central engine controller via a conventional plug contact.

If, however, the hybrid holder is mounted on the engine add-on component, it is locked in the upper area of the engine add-on component in the form of a glow plug and the part of the hybrid holder having a trough-shaped recess for accommodating the evaluation electronics is swiveled into a lowered position. In this mounting position, the lowered part of the hybrid holder and an upper front surface of the engine add-on component form a mounting plane. In this mounting plane, the hybrid may be inserted in the trough-shaped recess of the hybrid holder and electrically contacted on one side. The signal lines electrically contacted with the evaluation electronics in the form of a hybrid may then be contacted in the same mounting plane with electrical terminals which are led out of the engine add-on component at the front surface, for example. This approach offers considerable advantages with regard to easy accessibility of the electrical contact points on the engine add-on component and on the hybrid and, on the other hand, allows length and angle differences to be compensated.

The swivel axis between the part of the hybrid holder, which is lockable in a form-locked manner on the engine add-on component, and the part of the hybrid holder which accommodates the evaluation electronics may be designed as a film hinge, a rotary hinge, or also as a lever hinge. To limit swiveling, stop cams and latches may be provided, for example. The part of the hybrid holder which is accommodated on the engine add-on component may be snapped or pressed onto same, which simplifies mounting considerably.

If the hybrid holder is manufactured as an injection-molded plastic part, for example, then the swivel axis may be designed in an advantageous manner as a film hinge in the form of a taper of the plastic material. This represents a very simple and cost-effectively producible possibility to implement a swivel axis.

### BRIEF DESCRIPTION OF THE DRAWING

FIG. 1 shows a hybrid holder whose one part is latched on an engine add-on component and whose other part accommodating the evaluation electronics is shown in a lowered position as well as in a raised position.

### DETAILED DESCRIPTION

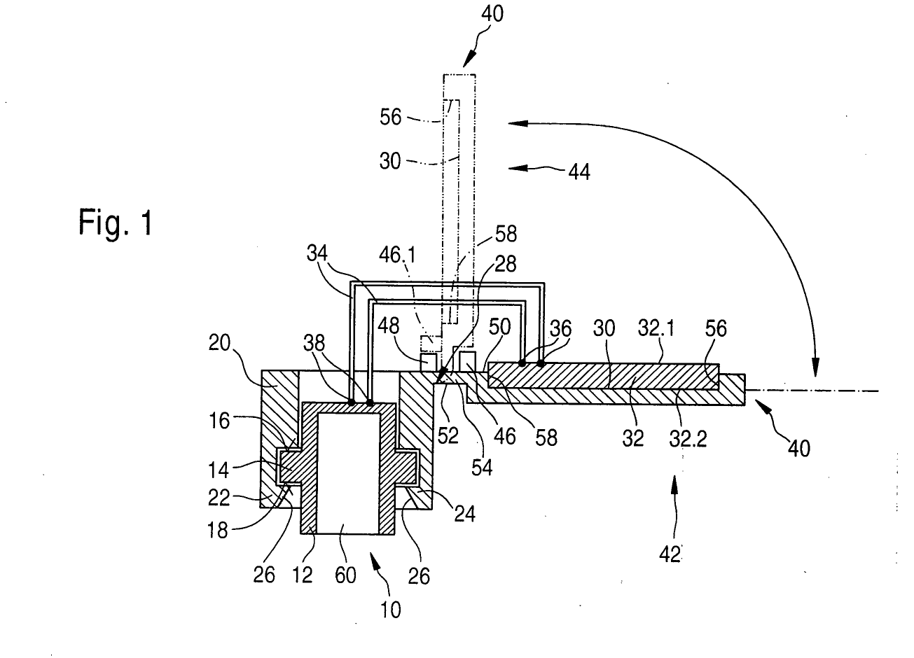

It is apparent from the representation in FIG. 1 that an engine add-on component 10 has a flange 14 extending into its head area. The engine add-on component may be a glow plug, for example, such as is used in compression-ignition internal combustion engines. For example, combustion chamber pressure sensors may be accommodated in glow plugs which are to be connected to evaluation electronics 32 on the front side of engine add-on component 10.

It is apparent from the representation in FIG. 1 that engine add-on component 10 includes a body 12 of an essentially cylindrical design, flange 14 running on the outer circumference of the component. Flange 14 includes a first ring surface 16 and a second ring surface 18. One part of a hybrid holder 20 is detachably fastened to flange 14 of engine add-on component 10. For this purpose, hybrid holder 20 has at least one first snap connection 22 or possibly a second snap connection 24. Instead of snap connections 22 and 24 shown in the FIGURE, latches or the like may be provided to ensure detachable fastening between hybrid holder 20 and engine add-on component 10.

Snap connections 22 and 24, shown in FIG. 1, each include mounting bevels 26 in order to make widening of snap connections 22 and 24 possible when they are slipped onto flange 14 when hybrid holder 20 is mounted on engine add-on component 10. As soon as the recesses of first and second snap connections 22 and 24 have overlapped flange 14, the protrusions of snap connections 22 and 24 grip second ring surface 18 in such a way that hybrid holder 20 is detachably fastened on engine add-on component 10.

In addition, hybrid holder 20 includes a set-up axis 28 which is designed in the representation according to FIG. 1 as a film hinge due to a cross-section reduction 54. Instead of cross section reduction 54, it is also conceivable to design a rotary hinge or a tilting hinge as swivel axis 28. A hybrid 32 is inserted into a receiving trough 30 of hybrid holder 20. The top side of hybrid 32 is identified by reference numeral 32.1, while the bottom side of hybrid 32 is identified by reference numeral 32.2. Hybrid 32 situated in receiving trough 30 is secured against shifting by a first limit 56 and a second limit 58 in receiving trough 30.

An attachment point 40 for a plug contact is provided on hybrid holder 20 in the area of first limit 56, hybrid holder 20 including accommodated evaluation electronics 32 being electrically connectable, in a raised position 44, to an engine controller of an internal combustion engine, for example, via the attachment point.

It is apparent from the representation in FIG. 1 that hybrid 32 is easily accessible in lowered position 42 of receiving trough 30. On top side 32.1 of hybrid 32, contacting lines 34 may thus be connected to hybrid 32 at a contact point 36. On the other hand, contacting lines 34 are electrically connected at a contact point 38 on the front side of engine add-on component 10, a glow plug for example. It should be pointed out that the planes in which contact point 36 and contact point 38 are situated on engine add-on component 10 are oriented in the same way such that the front side of engine add-on component 10 and top side 32.1 of hybrid 32, albeit having an offset, form one plane which ensures good accessibility of contact points 36 and 38. After establishing the electrical contact of the sensor element contained in engine add-on component 10 with hybrid 32 via contacting lines 34, the part of the hybrid holder which includes receiving trough 30 is moved from lowered position 42 into raised position 44 depicted in a dashed line. In the process, a stop cam 46, which is provided on a top side 50 of hybrid holder 20, moves into a stop position 46.1 (depicted in a dashed line) and hits a stop 48, which optionally limits the rising motion, stop 48 being also provided on top side 50 of hybrid holder 20. As mentioned previously, set-up axis 28 is represented by a cross-section reduction 54 between top side 50 and bottom side 52 of hybrid holder 20 in this exemplary embodiment. Engine add-on component 10 in the form of a glow plug includes a hollow space 60 through which the sensor element is formed (not depicted in the FIGURE). The sensor element accommodated above hollow space 60, which may be a combustion chamber pressure sensor, for example, is connected at contact point 38 to contacting lines 34 which in turn are electrically connected at contact point 36 to top side 32.1 of hybrid 32.

If the part of hybrid holder 20, which includes receiving trough 30, is moved from lowered position 42 into raised position 44, attachment point 40 for a plug contact situated in lowered position 42 in the area of first limit 46 is moved from the vertical position into the horizontal position in such a way that the attachment point is also easily accessible from above. In the event of disassembly, i.e., pulling the plug from attachment point 40, this simplifies accessibility considerably. If, after the plug is pulled from attachment point 40 of hybrid holder 20, the part of hybrid holder 20 containing receiving trough 30, which is in raised position 44, is again moved into lowered position 42, contact points 36 and 38, and contacting lines 34, which connect the sensor element to evaluation electronics 32, are easily accessible since they are situated in one plane. The plane is defined by the front side of engine add-on component 10, in which contact point 38 is situated, and by top side 32.1 of hybrid 32. Stop 48 on top side 50 of hybrid holder 20 is used for limiting the swivel path of the moveable part of hybrid holder 20 from lowered position 42 into raised position 44. In addition, the swivel process into raised position 44 may be limited via stop 48 in cooperation with stop cam 46 on top side 50 of the moveable part of hybrid holder 20. Instead of snap connections 22 and 24 shown in FIG. 1, hybrid holder 20 of engine add-on component 10 in the form of a glow plug may also be snap connected.

### LIST OF REFERENCE NUMERALS

10 engine add-on component
(glow plug)
12 body
14 flange
16 first ring surface
18 second ring surface
20 hybrid holder
22 first snap connection
24 second snap connection
26 mounting bevel
28 set-up axis
30 receiving trough
32 hybrid (evaluation electronics)
32.1 top side hybrid
32.2 bottom side hybrid
34 contacting lines
36 contact point hybrid
38 contact point of engine add-on component
40 attachment point for plug
42 lowered position
44 raised position
46 stop cam
46.1 raised position stop cam
48 stop
50 top side
52 bottom side
54 cross-section reduction
56 first limit
58 second limit
60 hollow space engine add-on component

1-10. (canceled)

11. A device for electrically connecting a sensor element, which is accommodated in an engine add-on component, to evaluation electronics, the device comprising:
contacting lines for electrically connecting the engine add-on component and the evaluation electronics to one another; and
a hybrid holder including a swiveling part for accommodating the evaluation electronics, the swiveling part being movable relative to a part of the hybrid holder which is attached to the engine add-on component in a form-locked manner.

12. The device according to claim 11, wherein the hybrid holder is detachably attached to the engine add-on component via form-locking elements.

13. The device according to claim 11, wherein the hybrid holder has a swiveling receiving trough for accommodating the evaluation electronics, the receiving trough being adjustable from a lowered position into a raised position.

14. The device according to claim 13, wherein in the lowered position of the receiving trough an electrical contact point of the engine add-on component and an electrical contact point of the evaluation electronics are situated substantially in one plane.

15. The device according to claim 13, wherein the receiving trough is movable around an axis which is one of a film hinge, a rotary hinge, and a lever hinge.

16. The device according to claim 13, wherein an attachment point for a plug element is situated on the receiving trough.

17. The device according to claim 13, wherein in the lowered position of the receiving trough the evaluation electronics and the engine add-on component are accessible from the same direction.

18. The device according to claim 13, wherein a swivel motion of the receiving trough from the lowered position into the raised position is limited by a stop of the hybrid holder.

19. The device according to claim 11, wherein the hybrid holder includes at least one form-locking element including at least one of a snap connection and a latch, using which the hybrid holder is attached to a flange of the engine add-on component.

20. The device according to claim 11, wherein the engine add-on component includes a glow plug containing a combustion chamber pressure sensor.
